(19) United States
(12) Patent Application Publication
(10) Pub. No.: US 2026/0143802 A1
(43) Pub. Date: May 21, 2026

(54) INTEGRATED CIRCUIT DEVICES INCLUDING GATE-ALL-AROUND TRANSISTORS HAVING CHANNEL SUPPORTS AND METHODS OF FORMING THE SAME

(71) Applicant: Samsung Electronics Co., Ltd., Suwon-si (KR)

(72) Inventors: Kibyung Park, Watervliet, NY (US); Hayoung Jeon, Hwaseong-si (KR); Edward Namkyu Cho, Slingerlands, NY (US); Kang-ill Seo, Springfield, VA (US)

(21) Appl. No.: 19/311,372

(22) Filed: Aug. 27, 2025

Related U.S. Application Data
(60) Provisional application No. 63/722,756, filed on Nov. 20, 2024.
(60) Provisional application No. 63/793,171, filed on Apr. 23, 2025.

(51) Int. Cl. H10D 84/85; H10D 84/01

(52) U.S. Cl. CPC H10D 84/851; H10D 84/0167; H10D 84/017; H10D 84/0184; H10D 84/856

(57) ABSTRACT

An integrated circuit device includes a substrate, a source/drain region on the substrate, a plurality of channel layers spaced apart in a first direction perpendicular to an upper surface of the substrate and electrically connected to the source/drain region, a gate structure extending in a second direction parallel to the upper surface of the substrate and at least partially surrounding the channel layers, and a channel support between adjacent ones of the channel layers in the first direction. The gate structure extends on opposing side surfaces of the channel support in the second direction.

### RELATED APPLICATIONS

The present application claims the benefit of U.S. Provisional Patent Application Ser. No. 63/722,756, entitled “INTEGRATED CIRCUIT DEVICES AND METHODS OF FORMING THE SAME,” filed on Nov. 20, 2024, with the United States Patent and Trademark Office, and U.S. Provisional Patent Application Ser. No. 63/793,171, entitled “INTEGRATED CIRCUIT DEVICES AND METHODS OF FORMING THE SAME,” filed on Apr. 23, 2025, with the United States Patent and Trademark Office, the disclosures of both of which are hereby incorporated by reference herein in their entirety.

### TECHNICAL FIELD

The present disclosure generally relates to the field of integrated circuit devices and, more particularly, to integrated circuit devices including gate-all-around transistors and methods of forming the same.

### BACKGROUND

The size of transistors in integrated circuit devices has continued to decrease to maintain downscaling of logic elements. For example, scaling of field-effect transistors (FETs) has led to advancements in semiconductor technology, including increased integration density, improved performance, and reduced power consumption. Planar FETs, however, may face challenges as device dimensions shrink due to short-channel effects and poor gate control over the channel. To overcome these challenges, multigate transistor structures such as FinFETs have been proposed. FinFETs improve gate control by wrapping the gate around three sides of the channel. Although FinFETs have extended transistor scaling, issues related to leakage current and poor gate control may still exist at advanced technology nodes.

Gate-All-Around (GAA) transistors have been proposed as an advanced transistor architecture to overcome the limitations of FinFETs. In GAA transistors, the gate wraps around the channel on upper, lower, and side surfaces thereof. This full gate wrap-around may provide superior electrostatic control over the channel, while suppressing leakage current and short-channel effects.

### SUMMARY

Example embodiments of the present application result, in part, from the realization that channel layers of transistors included in integrated circuit devices may be susceptible to physical deformation during fabrication and/or operation of the integrated circuit devices. For example, vertically stacked channel layers may be susceptible to a bending phenomenon where portions of the channel layers sag downwards between adjacent source/drain regions. Pursuant to example embodiments herein, integrated circuit devices are provided that include transistors having channel supports between adjacent channel layers. The channel supports may provide mechanical stability for the channel layers to mitigate or avoid physical deformation thereto such as bending of the channel layers during fabrication and/or operation of the integrated circuit devices.

An integrated circuit device, according to some embodiments herein, may include a substrate, a source/drain region on the substrate, a plurality of channel layers spaced apart in a first direction perpendicular to an upper surface of the substrate and electrically connected to the source/drain region, a gate structure extending in a second direction parallel to the upper surface of the substrate and at least partially surrounding the channel layers, and a channel support between adjacent ones of the channel layers in the first direction. The gate structure may extend on opposing side surfaces of the channel support in the second direction.

An integrated circuit device, according to some embodiments herein, may include a substrate, a pair of source/drain regions on the substrate, a plurality of channel layers spaced apart in a first direction perpendicular to an upper surface of the substrate and between the pair of source/drain regions in a second direction parallel to the upper surface of the substrate, a gate structure extending in a third direction parallel to the upper surface of the substrate and intersecting the second direction, the gate structure at least partially surrounding the channel layers, and a channel support between adjacent ones of the channel layers in the first direction. At least one of the channel layers may protrude beyond opposing side surfaces of the channel support in the third direction.

A method of forming an integrated circuit device, according to some embodiments herein, may include forming a plurality of channel layers on a substrate, the channel layers spaced apart in a first direction perpendicular to an upper surface of the substrate, forming a channel support layer between the channel layers, the channel support layer comprising an insulating material, selectively removing portions of the channel support layer without removing all of the channel support layer to form at least one channel support between adjacent ones of the channel layers in the first direction, and forming a gate structure on the channel layers and on the at least one channel support, the gate structure at least partially surrounding the channel layers and extending on opposing side surfaces of the at least one channel support in a second direction intersecting the first direction.

Other devices, apparatuses, and/or methods according to example embodiments will become more apparent to one of ordinary skill in the art upon review of the following drawings and detailed description. It is intended that all such additional embodiments, in addition to any and all combinations of the above embodiments, be included within this description, be within the scope of the present disclosure, and be protected by the accompanying claims.

### BRIEF DESCRIPTION OF THE DRAWINGS

FIG. 1A is a schematic block diagram illustrating a transistor stack of an integrated circuit device according to some embodiments.

FIG. 1B is a schematic plan view illustrating an integrated circuit device according to some embodiments.

FIG. 1C is a schematic cross-sectional view taken along line A-A′ of FIG. 1B.

FIG. 1D is a schematic cross-sectional view taken along line B-B′ of FIG. 1B.

FIG. 1E is a schematic perspective view illustrating a transistor of an integrated circuit device according to some embodiments.

FIG. 1F is a schematic top view illustrating the transistor of FIG. 1E according to some embodiments.

FIG. 2 is a flowchart illustrating a method of forming an integrated circuit device according to some embodiments.

FIGS. 3, 4A, 4B, 5A, 5B, 6A, 6B, 7, 8, 9, 10, 11A, 11B, 12A, and 12B are schematic cross-sectional views illustrating a method of forming an integrated circuit device according to some embodiments.

### DETAILED DESCRIPTION

Integrated circuit devices may include transistors that have a gate-all-around (GAA) structure. For example, a GAA field-effect transistor (GAAFET) may include a gate that wraps around the channel on upper, lower, and side surfaces thereof. The GAA transistor structure offers performance advantages for integrated circuit devices, such as superior electrostatic control over the channel, along with reduced leakage current and mitigation of short-channel effects. GAA transistors may include vertically stacked channel layers that are implemented as nanosheets or nanowires to increase drive current while maintaining a small footprint for the transistors. In some embodiments, GAA transistors may be implemented as stacked transistors, such as three-dimensional stacked FETs (3DSFETs), to further reduce the footprint of the transistors and improve integration density.

Despite their advantages, challenges remain in the fabrication and operation of GAA transistors. For example, maintaining the mechanical stability of the channel layers may prove challenging during fabrication and/or operation of the GAA transistors (or integrated circuit devices), particularly since the channel layers may be vertically stacked and may form a bridge structure in which the channel layers are suspended during device fabrication. More particularly, the channel layers may be subjected to heat, stress, and/or surface tension during fabrication and/or operation of the GAA transistors (or integrated circuit devices), which may lead to bending (or sagging) of the channel layers along with other forms of physical deformation. Deformation of the channel layers may be exacerbated as the channel length increases, and thus design rules often limit the channel length in GAA transistors to avoid deformation of the channel layers. The limited channel length, however, may lead to decreased performance of the GAA transistors (or integrated circuit devices) due to increased short-channel effects, higher leakage current and on-state resistance, and/or reduced design flexibility.

Pursuant to example embodiments herein, integrated circuit devices are provided that include transistors (e.g., GAAFETs) having channel supports between adjacent channel layers. The channel supports may provide mechanical stability for the channel layers to mitigate or avoid physical deformation thereto such as bending of the channel layers during fabrication and/or operation of the integrated circuit devices. Accordingly, the performance and reliability of the integrated circuit devices may be improved. Further, the channel supports may allow for the length of the channel layers to be extended without risking deformation, which may offer performance advantages and increased design flexibility for the integrated circuit devices.

Some examples of embodiments of the present disclosure are described in greater detail hereinafter with reference to the attached figures.

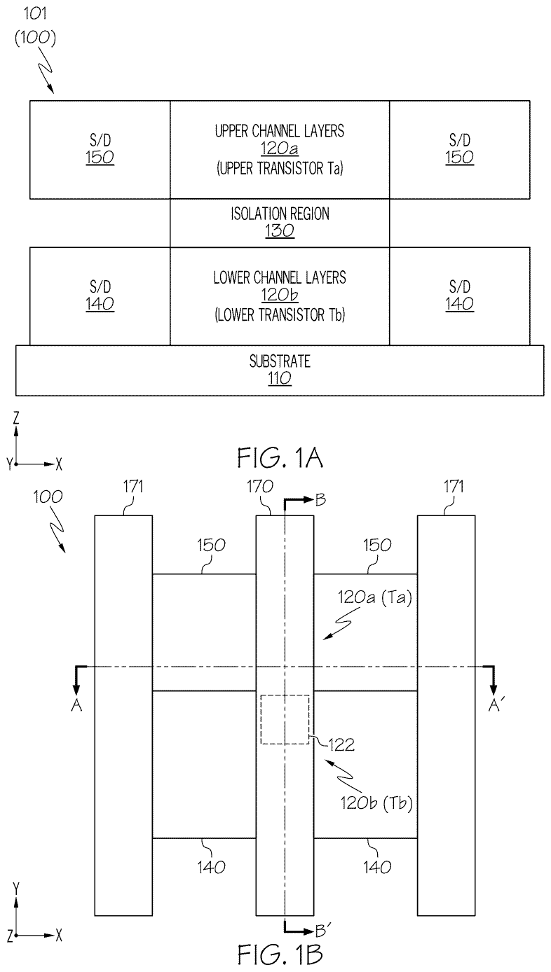

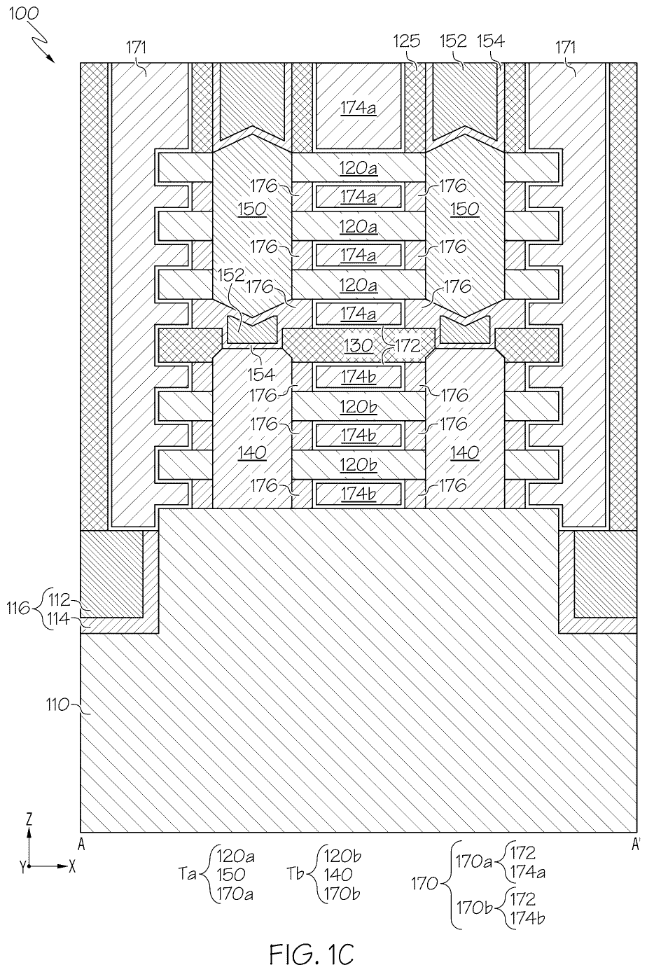

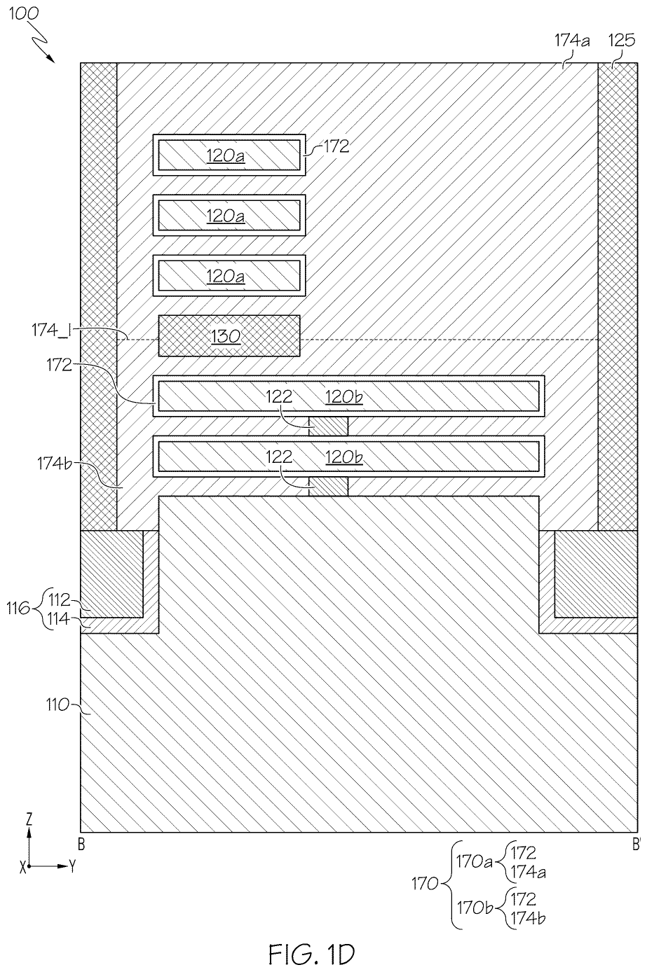

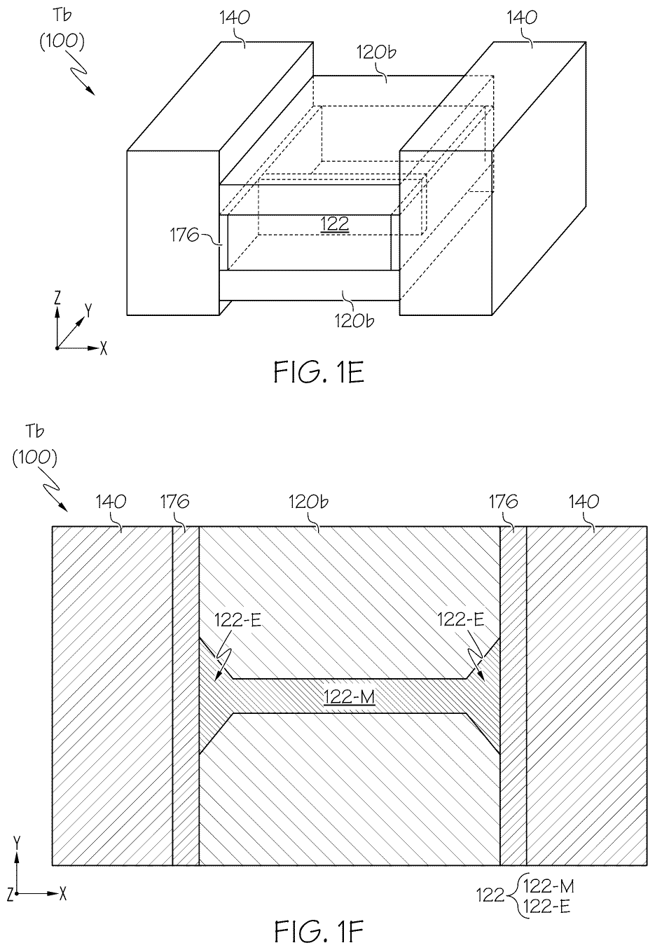

FIG. 1A is a schematic block diagram illustrating a transistor stack of an integrated circuit device according to some embodiments.

Referring to FIG. 1A, an integrated circuit device 100 includes a substrate 110 and a transistor stack 101 on an upper surface (i.e., a frontside) of the substrate 110. The substrate 110 may extend in a first direction X (also referred to as a first horizontal direction) and a second direction Y (also referred to as a second horizontal direction). The first direction X and the second direction Y may be parallel to the upper surface and/or lower surface of the substrate 110. For example, the first direction X may intersect the second direction Y. In some embodiments, the first direction X may be perpendicular (or orthogonal) to the second direction Y.

The upper surface of the substrate 110 is opposite to a lower surface (i.e., a backside) of the substrate 110 in a third direction Z (also referred to as a vertical direction). For example, the third direction Z may intersect the first direction X and the second direction Y. In some embodiments, the third direction Z may be perpendicular (or orthogonal) to the first direction X and/or the second direction Y. The third direction Z may be perpendicular to the upper surface and/or lower surface of the substrate 110.

In some embodiments, the substrate 110 may include or may be formed of insulating material(s), for example, silicon oxide, silicon oxynitride, silicon nitride, silicon carbonitride, silicon boron nitride, silicon boron carbonitride, and/or a low-k dielectric material. The low-k dielectric material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectrics. In some embodiments, the substrate 110 may include or may be formed of semiconductor material(s), for example, Si, Ge, SiGe, GaP, GaAs, SiC, SiGeC and/or InP. For example, the substrate 110 may be insulating layer(s), a bulk substrate (e.g., a bulk silicon wafer) and/or a semiconductor-on-insulator (SOI) substrate. A thickness of the substrate 110 in the third direction Z may be, for example, in a range of (about) 50 nanometers (nm) to 100 nm, but is not limited thereto.

The transistor stack 101 includes a lower transistor Tb having a stack of lower semiconductor channel layers 120b, and an upper transistor Ta having a stack of upper semiconductor channel layers 120a. The channel layers 120a, 120b may include, for example, semiconductor material(s) (e.g., Si, Ge, SiGe, GaP, GaAs, SiC, SiGeC and/or InP). In some embodiments, the channel layers 120a, 120b may be nanosheets that may have a thickness, for example, in a range of (about) 1 nm to 100 nm in the third direction Z, or may be nanowires that may have a circular or elliptical cross-section with a diameter, for example, in a range of (about) 1 nm to 100 nm.

The lower transistor Tb is between, in the third direction Z, the upper transistor Ta and the substrate 110. For example, the upper transistor Ta may be on the lower transistor Tb and may overlap the lower transistor Tb in the third direction Z. As used herein, “an element A overlaps an element B in a direction” (or similar language) means that there is at least one straight line that extends in the direction and intersects both the elements A and B. The transistor stack 101 may also include an isolation region 130, such as a middle dielectric isolation (MDI) region. The isolation region 130 may, in some embodiments, serve as a spacer between the upper and lower transistors Ta, Tb. The isolation region 130 may thus also be referred to herein as a “spacer.”

The lower channel layers 120b of the lower transistor Tb are between, in the first direction X, a pair of lower source/drain (S/D) regions 140 that are electrically connected to the lower channel layers 120b. Likewise, the upper channel layers 120a of the upper transistor Ta are between, in the first direction X, a pair of upper source/drain regions 150 that are electrically connected to the upper channel layers 120a. The lower source/drain regions 140 may be between, in the third direction Z, the upper source/drain regions 150 and the substrate 110.

The lower source/drain regions 140 and the upper source/drain regions 150 may each include a semiconductor layer (e.g., a silicon (Si) layer, a silicon carbide (SiC) layer, and/or a silicon germanium (SiGe) layer) and may additionally include dopants in the semiconductor layer. For example, each of the lower and upper source/drain regions 140, 150 may include an epitaxial semiconductor layer having dopants (i.e., impurities) therein. In some embodiments, the upper source/drain regions 150 may include a different semiconductor material from that of the lower source/drain regions 140. As an example, the upper source/drain regions 150 may include silicon germanium, and the lower source/drain regions 140 may include silicon or silicon carbide, or vice versa. In some other embodiments, the upper source/drain regions 150 may include the same semiconductor material as the lower source/drain regions 140. The lower source/drain regions 140 may be on the substrate 110, and the upper source/drain regions 150 may be on the lower source/drain regions 140.

In some embodiments, the lower source/drain regions 140 have a first conductivity type and the upper source/drain regions 150 have a second conductivity type. As used herein, the terms “first conductivity type” and “second conductivity type” are used to indicate either n-type or p-type, where the first and second conductivity types are different from each other. Thus, if a first region of a device has a first conductivity type and a second region of the device has a second conductivity type, this means either that the first region has n-type conductivity and the second region has p-type conductivity or, alternatively, that the first region has p-type conductivity and the second region has n-type conductivity. For example, the lower source/drain regions 140 may include n-type impurities (e.g., phosphorus (P), arsenic (As), antimony (Sb), etc.) and the upper source/drain regions 150 may include p-type impurities (e.g., boron (B), gallium (Ga), indium (In), etc.), or vice versa.

The upper and lower transistors Ta, Tb may be stacked in the third direction Z on the substrate 110. In some embodiments, the lower transistor Tb and the upper transistor Ta may have complementary conductivity types to form a complementary metal-oxide-semiconductor (CMOS) structure. For example, the lower transistor Tb may have a first conductivity type, while the upper transistor Ta may have a second conductivity type. In some embodiments, the upper and lower transistors Ta, Tb may be PMOS and NMOS transistors, respectively, or vice versa. For example, the upper and lower transistors Ta, Tb may each be a three-dimensional (3D) field-effect transistor (FET) such as a gate-all-around FET (GAAFET). Also, while illustrated with reference to the lower transistor Tb and the upper transistor Ta, it will be understood that the transistor stack 101 is not limited to a two-transistor arrangement, and may include additional transistors that are vertically stacked on the substrate 110, in some other embodiments. For simplicity of illustration, only one transistor stack 101 is shown in FIG. 1A. It will be understood, however, that the integrated circuit device 100 may include two, three, four, or more transistor stacks 101 in some embodiments.

FIG. 1B is a schematic plan view (or layout view) illustrating an integrated circuit device according to some embodiments. For simplicity of illustration, FIG. 1B only shows some elements of the integrated circuit device 100. As shown in FIG. 1B, the integrated circuit device 100 includes a gate structure 170 on the upper channel layers 120a of the upper transistor Ta and the lower channel layers 120b of the lower transistor Tb. In some embodiments, the integrated circuit device 100 also includes dummy gate structures 171. The integrated circuit device 100 may also include channel supports 122 (shown by a dashed box in FIG. 1B) that overlap with the lower channel layers 120b and the gate structure 170 in the third direction Z. The channel supports 122 are described in greater detail below.

A line A-A′ passes through the upper and lower transistors Ta, Tb along a channel width of the upper and lower channel layers 120a, 120b in the first direction X. A line B-B′ passes lengthwise (i.e., longitudinally) through the gate structure 170 and the upper and lower channel layers 120a, 120b in the second direction Y. FIG. 1C is a schematic cross-sectional view taken along line A-A′ of FIG. 1B. FIG. 1D is a schematic cross-sectional view taken along line B-B′ of FIG. 1B.

Referring to FIGS. 1B, 1C, and 1D, the gate structure 170 may include an upper gate structure 170a and a lower gate structure 170b. The upper transistor Ta includes the upper channel layers 120a, the pair of upper source/drain regions 150, and the upper gate structure 170a. The lower transistor Tb includes the lower channel layers 120b, the pair of lower source/drain regions 140, and the lower gate structure 170b. The lower transistor Tb and the upper transistor Ta comprise the transistor stack 101 (see FIG. 1A) of the integrated circuit device 100.

The pair of upper source/drain regions 150 may be spaced apart from each other (e.g., in the first direction X), with the upper gate structure 170a therebetween. The pair of lower source/drain regions 140 may be spaced apart from each other (e.g., in the first direction X), with the lower gate structure 170b therebetween. In some embodiments, widths of the lower source/drain regions 140 in the second direction Y may be greater than widths of the upper source/drain regions 150 in the second direction Y, and thus portions of the lower source/drain regions 140 may be free of overlap in the third direction Z with the upper source/drain regions 150, as shown in FIG. 1B. The upper channel layers 120a may be between (e.g., in the first direction X) the pair of upper source/drain regions 150. The upper source/drain regions 150 are electrically connected to the upper channel layers 120a. As shown in FIG. 1C, the upper channel layers 120a may be spaced apart from each other in the third direction Z, with the upper gate structure 170a therebetween. Although FIG. 1C illustrates three upper channel layers 120a, embodiments of the present disclosure are not limited thereto. In some embodiments, the integrated circuit device 100 may include more than three upper channel layers 120a or less than three upper channel layers 120a. The lower channel layers 120b may be between (e.g., in the first direction X) the pair of lower source/drain regions 140. The lower source/drain regions 140 are electrically connected to the lower channel layers 120b. As shown in FIG. 1C, the lower channel layers 120b may be spaced apart from each other in the third direction Z, with the lower gate structure 170b therebetween. Although FIG. 1C illustrates two lower channel layers 120b, embodiments of the present disclosure are not limited thereto. In some embodiments, the integrated circuit device 100 may include more than two lower channel layers 120b.

The upper gate structure 170a may be on the upper channel layers 120a of the upper transistor Ta, and the lower gate structure 170b may be on the lower channel layers 120b of the lower transistor Tb. The upper gate structure 170a includes a gate insulator 172 and an upper conductive gate 174a. The upper conductive gate 174a may be between (e.g., in the third direction Z) the upper channel layers 120a and may be spaced apart from the upper source/drain regions 150 (e.g., in the first direction X) by inner spacers 176. The inner spacers 176 may be on side surfaces (i.e., sidewalls) of the gate insulator 172 and the upper conductive gate 174a and may be between, in the third direction Z, the upper channel layers 120a. The inner spacers 176 may include insulating material(s) (e.g., silicon oxide, silicon oxynitride, silicon nitride, silicon carbonitride, silicon boron carbonitride, and/or a low-k material). In some embodiments, the inner spacers 176 may include a nitride material such as silicon nitride.

The lower gate structure 170b includes the gate insulator 172 and a lower conductive gate 174b. The lower conductive gate 174b may be between (e.g., in the third direction Z) the lower channel layers 120b and may be spaced apart from the lower source/drain regions 140 (e.g., in the first direction X) by the inner spacers 176. The inner spacers 176 may be on side surfaces (i.e., sidewalls) of the gate insulator 172 and the lower conductive gate 174b and may be between, in the third direction Z, the lower channel layers 120b.

In some embodiments, the inner spacers 176 may contact (e.g., may be directly on) the lower source/drain regions 140, the upper source/drain regions 150, the lower channel layers 120b, the upper channel layers 120a, and/or the gate insulator 172. The inner spacers 176 may be between the lower gate structure 170b and the lower source/drain regions 140 (e.g., in the first direction X), and between the upper gate structure 170a and the upper source/drain regions 150 (e.g., in the first direction X). Side surfaces of the lower channel layers 120b may contact (e.g., may be directly on) the lower source/drain regions 140, and side surfaces of the upper channel layers 120a may contact (e.g., may be directly on) the upper source/drain regions 150.

The upper conductive gate 174a and the lower conductive gate 174b may each include a metal material (e.g., tungsten (W), aluminum (Al), copper (Cu), molybdenum (Mo), cobalt (Co), and/or ruthenium (Ru)) and/or a semiconductor material. In some embodiments, the upper conductive gate 174a and the lower conductive gate 174b may each include a metal layer and work function layer(s) (e.g., a TiN layer, a TaN layer, a TiAl layer, a TiC layer, a TiAlC layer, a TiAlN layer and/or a WN layer). For example, the work function layer(s) may be provided between the metal layer and the gate insulator 172. In some embodiments, the work function layer(s) may separate the metal layer from the gate insulator 172. In some embodiments, the upper conductive gate 174a and the lower conductive gate 174b may include the same metal material. In some other embodiments, the upper conductive gate 174a and the lower conductive gate 174b may include different metal materials. In some embodiments, the upper and lower conductive gates 174a, 174b may comprise an integrated unitary structure (e.g., formed by the same process or the same series of processes), but the present disclosure is not limited thereto.

The gate insulator 172 extends between the upper channel layers 120a and the upper conductive gate 174a, and between the lower channel layers 120b and the lower conductive gate 174b. The gate insulator 172 may surround the upper and lower conductive gates 174a, 174b and may separate (i.e., insulate) the upper and lower conductive gates 174a, 174b from the upper and lower channel layers 120a, 120b, respectively. The gate insulator 172 may include a single layer or multiple layers (e.g., a silicon oxide layer and/or a high-k material layer). For example, the high-k material layer may include Al₂O₃, HfO₂, ZrO₂, HfZrO₄, TiO₂, Sc₂O₃, Y₂O₃, La₂O₃, Lu₂O₃, Nb₂O₅ and/or Ta₂O₅. It will be understood that “an element A surrounds an element B” (or similar language) as used herein means that the element A is at least partially around the element B but does not necessarily mean that the element A completely encloses the element B.

The isolation region 130 may be a spacer that separates the lower channel layers 120b of the lower transistor Tb from the upper channel layers 120a of the upper transistor Ta. The isolation region 130 may be between the upper gate structure 170a and the lower gate structure 170b (e.g., in the third direction Z). The isolation region 130 may include, for example, one or more isolation layers including insulating material(s) (e.g., silicon oxide, silicon oxynitride, silicon nitride, silicon carbonitride, silicon boron carbonitride, and/or a low-k material). Although FIGS. 1C and 1D illustrate the isolation region 130 as a single layer, in some embodiments, the isolation region 130 may include multiple layers.

Upper spacers 125 may be on opposing side surfaces of the gate structure 170. The upper spacers 125 may also be on opposing side surfaces of the dummy gate structures 171. The upper spacers 125 may include, for example, insulating material(s) (e.g., silicon oxide, silicon oxynitride, silicon nitride, silicon carbonitride, silicon boron carbonitride, and/or a low-k material).

The integrated circuit device 100 may further include a first insulating layer 152 and a first insulating liner 154 on an upper surface of each of the upper source/drain regions 150 and between, in the third direction Z, the lower and upper source/drain regions 140, 150. The first insulating layer 152 and the first insulating liner 154 may separate the lower source/drain regions 140 from the upper source/drain regions 150. The first insulating liner 154 may extend adjacent the first insulating layer 152 and may be between the first insulating layer 152 and the lower and upper source/drain regions 140, 150. The first insulating layer 152 and the first insulating liner 154 may include, for example, insulating material(s) (e.g., silicon oxide, silicon oxynitride, silicon nitride, silicon carbonitride, silicon boron carbonitride, and/or a low-k material). In some embodiments, the first insulating layer 152 and the first insulating liner 154 may include different insulating materials. For example, the first insulating layer 152 may include silicon oxide and the first insulating liner 154 may include silicon nitride, although embodiments of the present disclosure are not limited thereto.

Shallow trench isolation (STI) regions 116 may be formed in the substrate 110 on opposite sides of the upper and lower transistors Ta, Tb (e.g., in the first direction X). The STI regions 116 may include a second insulating layer 112 and a second insulating liner 114. The second insulating liner 114 may extend adjacent the second insulating layer 112 and may be between the second insulating layer 112 and the substrate 110. The second insulating layer 112 and the second insulating liner 114 may include, for example, insulating material(s) (e.g., silicon oxide, silicon oxynitride, silicon nitride, silicon carbonitride, silicon boron carbonitride, and/or a low-k material). In some embodiments, the second insulating layer 112 and the second insulating liner 114 may include different insulating materials. For example, the second insulating layer 112 may include silicon oxide and the second insulating liner 114 may include silicon nitride, although embodiments of the present disclosure are not limited thereto. The STI regions 116 may define the active regions of the integrated circuit device 100 and may isolate (e.g., electrically isolate) adjacent transistor stacks 101 (see FIG. 1A).

The dummy gate structures 171 may be formed on the STI regions 116. For example, the dummy gate structures 171 may be gate structures that do not function electrically (e.g., non-active gate structures) and may be formed to replicate a physical structure of the gate structure 170. In some embodiments, the gate insulator 172 (or a spacer) may be on side surfaces of the dummy gate structures 171, but the present disclosure is not limited thereto.

In some embodiments, the integrated circuit device 100 further includes an upper connection structure (not shown) on the upper and lower transistors Ta, Tb. The upper connection structure may include conductive elements (e.g., wire(s) and/or via plug(s)) and insulating elements (e.g., interlayer(s) and/or spacer(s)). For example, the upper connection structure may include an interlayer insulating layer, conductive wires (e.g., metal wires) that are provided in the interlayer insulating layer and are stacked in the third direction Z, and conductive via plugs (e.g., metal via plugs), each of which may electrically connect two conductive wires that are spaced apart from each other in the third direction Z. For ease of illustration, the upper connection structure is not shown in the cross-sectional views of FIGS. 1C-D. It will be understood, however, that the conductive elements of the upper connection structure may be electrically connected to, for example, one or more of the upper source/drain regions 150, one or more of the lower source/drain regions 140, and/or the gate structure 170 for power and/or data delivery thereto.

In some embodiments, the integrated circuit device 100 may further include a backside power delivery network (BSPDN) structure (not shown) on the lower surface (i.e., the backside) of the substrate 110. For example, backside contact structures (not shown) may electrically connect the BSPDN structure to one or more of the lower source/drain regions 140. The BSPDN structure may include a backside insulator and one or more backside power rails provided in the backside insulator. For example, the backside power rail may be electrically connected to a power source with a predetermined voltage (e.g., a drain voltage (Vdd) and/or a source voltage (Vss)). For ease of illustration, the BSPDN structure is not shown in the cross-sectional views of FIGS. 1C-D. It will be understood, however, that the BSPDN structure may be electrically connected to, for example, one or more of the lower source/drain regions 140 and/or one or more of the upper source/drain regions 150 for power delivery thereto. In some other embodiments, the BSPDN structure may be omitted.

As shown in FIG. 1D, the lower gate structure 170b may surround the lower channel layers 120b. That is, the lower gate structure 170b (e.g., the lower conductive gate 174b) may be on an upper surface, a lower surface, and opposing side surfaces (i.e., opposing sidewalls) of each lower channel layer 120b, and hence the lower transistor Tb may have a GAA structure. For example, the lower gate structure 170b may be on opposing side surfaces of the lower channel layers 120b in the second direction Y, and the lower source/drain regions 140 may be on opposing side surfaces of the lower channel layers 120b in the first direction X. The gate insulator 172 may be between each lower channel layer 120b and the lower conductive gate 174b, and may separate the lower conductive gate 174b from the lower channel layers 120b.

The upper gate structure 170a may surround the upper channel layers 120a. That is, the upper gate structure 170a (e.g., the upper conductive gate 174a) may be on an upper surface, a lower surface, and opposing side surfaces (i.e., opposing sidewalls) of each upper channel layer 120a, and hence the upper transistor Ta may have a GAA structure. The gate insulator 172 may be between each upper channel layer 120a and the upper conductive gate 174a, and may separate the upper conductive gate 174a from the upper channel layers 120a.

The isolation region 130 separates and electrically isolates the lower channel layers 120b from the upper channel layers 120a. In some embodiments, the lower channel layers 120b may be wider, in the second direction Y, than the upper channel layers 120a. For example, in some embodiments, the lower channel layers 120b may be more than twice as wide as the upper channel layers 120a in the second direction Y. In some embodiments, the isolation region 130 may have the same width as the upper channel layers 120a in the second direction Y. In some other embodiments, different from that shown, the isolation region 130 may have the same width as the lower channel layers 120b in the second direction Y.

As shown in FIG. 1D, the upper gate structure 170a (e.g., the upper conductive gate 174a) and the lower gate structure 170b (e.g., the lower conductive gate 174b) may be in electrical contact with each other (i.e., may be electrically connected to each other) and may share an interface 174_I (shown by a dashed line in FIG. 1D). In some embodiments, a common gate signal may be applied to both the upper conductive gate 174a and the lower conductive gate 174b. In some other embodiments, different from that shown, the isolation region 130 may separate (e.g., electrically isolate) the upper conductive gate 174a from the lower conductive gate 174b, such that the upper and lower conductive gates 174a, 174b may be configured to receive separate gate signals.

The integrated circuit device 100 further includes channel supports 122 between adjacent ones of the lower channel layers 120b in the third direction Z, and between a lowermost one of the lower channel layers 120b and the substrate 110 in the third direction Z. In other words, the lower channel layers 120b may be spaced apart from each other in the third direction Z, with the channel support 122 therebetween. The channel supports 122 may be stacked and spaced apart from each other in the third direction Z, and may overlap the lower channel layers 120b and the substrate 110 in the third direction Z. In some embodiments, the channel supports 122 may be aligned in the third direction Z (i.e., may be vertically aligned). The channel supports 122 may include insulating material(s) (e.g., silicon oxide, silicon oxynitride, silicon nitride, silicon carbonitride, silicon boron carbonitride, and/or a low-k material). In some embodiments, the channel supports 122 may include an oxide material such as silicon oxide. For example, silicon oxide may offer advantages in terms of mechanical stability and structural support for the lower channel layers 120b, while also simplifying a fabrication process for the channel supports 122 and/or reducing costs associated therewith. In some other embodiments, the channel supports 122 may include an insulating material other than silicon oxide.

As shown in FIGS. 1B and 1D, the lower channel layers 120b may have a middle (or central) portion in the second direction Y, and the channel supports 122 may overlap with the middle portion of the lower channel layers 120b in the third direction Z. For example, the channel supports 122 may offer increased mechanical stability and structural support for the lower channel layers 120b when they overlap the middle portion of each lower channel layer 120b in the third direction Z. In some embodiments, each lower channel layer 120b may include a center point (or midpoint) in the second direction Y, and the channel supports 122 may overlap the center point of each lower channel layer 120b in the third direction Z. For example, the channel support 122 may be spaced apart from opposing side surfaces of each lower channel layer 120b in the second direction Y by substantially the same distance.

Each lower channel layer 120b may protrude beyond (i.e., extend beyond) opposing side surfaces of each channel support 122 in the second direction Y, which may allow the lower conductive gate 174b to extend around (i.e., wrap around) more surface area of the lower channel layers 120b, thereby advantageously increasing the electrostatic control (i.e., gate control) over the lower channel layers 120b. For example, end portions (e.g., opposite end portions) of each lower channel layer 120b in the second direction Y may be spaced apart from the channel supports 122 in the second direction Y and may be free of overlap with the channel supports 122 in the third direction Z. A width of each channel support 122 in the second direction Y may be less than a width of each lower channel layer 120b in the second direction Y. That is, each channel support 122 may be narrower in the second direction Y than each lower channel layer 120b. In some embodiments, the width of each lower channel layer 120b in the second direction Y may be at least two times the width of each channel support 122 in the second direction Y. That is, each lower channel layer 120b may be at least twice as wide in the second direction Y as each channel support 122. In some other embodiments, the width of each lower channel layer 120b in the second direction Y may be at least three times or at least four times the width of each channel support 122 in the second direction Y.

Although FIGS. 1B and 1D illustrate that the channel supports 122 overlap in the third direction Z (i.e., vertically overlap) with the center point of each lower channel layer 120b in the second direction Y, embodiments of the present disclosure are not limited thereto. In some other embodiments, one or more of the channel supports 122 may be offset from the center point of the lower channel layers 120b in the second direction Y. For example, one or more of the channel supports 122 may be closer to one side surface of a lower channel layer 120b in the second direction Y than the other opposing side surface of the lower channel layer 120b. Further, although FIG. 1D illustrates that one channel support 122 is between each adjacent pair of lower channel layers 120b in the third direction Z, embodiments of the present disclosure are not limited thereto. In some other embodiments, multiple channel supports 122 may be between each adjacent pair of lower channel layers 120b in the third direction Z and may be spaced apart from each other in the second direction Y (e.g., with portions of the lower conductive gate 174b therebetween).

The channel supports 122 may be in contact with (e.g., may be directly on) the lower gate structure 170b, the inner spacers 176 (see FIGS. 1E-F), and the substrate 110. For example, the channel supports 122 may be in contact with (e.g., may be directly on) the gate insulator 172 and the lower conductive gate 174b. In some embodiments, the gate insulator 172 and the inner spacers 176 may each include at least one different insulating material from the channel supports 122. For example, the gate insulator 172 may include a high-k material (e.g., Al₂O₃, HfO₂, ZrO₂, HfZrO₄, TiO₂, Sc₂O₃, Y₂O₃, La₂O₃, Lu₂O₃, Nb₂O₅ and/or Ta₂O₅), the inner spacers 176 may include a nitride material (e.g., silicon nitride), and the channel supports 122 may include silicon oxide. As used herein, the term “high-k material” refers to a material having a dielectric constant greater than that of silicon oxide (SiO₂). In some embodiments, the channel supports 122 may be thicker than the gate insulator 172.

As shown in FIG. 1D, a portion of the lower gate structure 170b between adjacent lower channel layers 120b may be on opposing side surfaces of the channel support 122 (e.g., in the second direction Y) and may be on upper and lower surfaces of the channel support 122. For example, the lower conductive gate 174b may be on (e.g., may be directly on) opposing side surfaces of the channel support 122 in the second direction Y, and the gate insulator 172 may be on (e.g., may be directly on) upper and lower surfaces of the channel support 122 in the third direction Z. In some embodiments, the gate insulator 172 may not be on a lower surface of a lowermost one of the channel supports 122. For example, the lowermost one of the channel supports 122 may be between a lowermost one of the lower channel layers 120b and the substrate 110 and, in some embodiments, may be directly on the substrate 110. The channel supports 122 may overlap each other in the third direction Z and may be aligned in the third direction Z. As shown in FIG. 1D, an uppermost one of the lower channel layers 120b may not have a channel support 122 thereon. That is, an upper surface of the uppermost one of the lower channel layers 120b may be free of a channel support 122 thereon. For example, an uppermost one of the channel supports 122 may be between an uppermost one of the lower channel layers 120b and another lower channel layer 120b therebelow.

In some embodiments, the channel supports 122 may not be formed between adjacent ones of the upper channel layers 120a. In other words, as shown in FIG. 1D, adjacent ones of the upper channel layers 120a may be free of channel supports 122 therebetween in the third direction Z. For example, a height of an uppermost one of the channel supports 122 in the third direction Z (e.g., relative to an upper surface of the substrate 110) may be less than a height of a lowermost one of the upper channel layers 120a in the third direction Z.

In some embodiments, the upper channel layers 120a may not overlap with (i.e., may be free of overlap with) the channel supports 122 in the third direction Z. For example, the upper channel layers 120a may be laterally spaced apart from the channel supports 122 in the second direction Y. As shown in FIG. 1D, widths of the upper channel layers 120a in the second direction Y are less than widths of the lower channel layers 120b in the second direction Y. As a result, the upper channel layers 120a may be less susceptible to bending (or sagging) or other forms of physical deformation than the lower channel layers 120b. Accordingly, the channel supports 122 may not be formed between the upper channel layers 120a, so that the upper conductive gate 174a may extend around (i.e., wrap around) more surface area of the upper channel layers 120a, thereby advantageously increasing the electrostatic control (i.e., gate control) over the upper channel layers 120a. In some other embodiments, different from that shown, the channel supports 122 may be formed between adjacent ones of the upper channel layers 120a (e.g., in the third direction Z).

FIG. 1E is a schematic perspective view illustrating a transistor of an integrated circuit device according to some embodiments. In particular, FIG. 1E is a schematic perspective view illustrating the lower transistor Tb of the integrated circuit device 100. The lower gate structure 170b (including the gate insulator 172 and the lower conductive gate 174b) and the lowermost one of the channel supports 122 described above with reference to FIGS. 1B-D are omitted in FIG. 1E to help illustrate example embodiments of the present disclosure. It will be understood, however, that the lower gate structure 170b may extend in the second direction Y between the lower channel layers 120b and may be on opposing side surfaces of the channel support 122 in the second direction Y, as described above with reference to FIG. 1D. Further, a pair of inner spacers 176 shown in FIG. 1E may be on opposite sides (e.g., in the first direction X) of the lower gate structure 170b. It will also be understood that the lowermost one of the channel supports 122 may be between the lowermost one of the lower channel layers 120b and the substrate 110, as described above with reference to FIG. 1D.

FIG. 1F is a schematic top view illustrating the transistor of FIG. 1E according to some embodiments. In particular, FIG. 1F is a schematic top view of the lower transistor Tb of the integrated circuit device 100. The lower gate structure 170b is omitted in FIG. 1F to help illustrate example embodiments of the present disclosure. The uppermost one of the lower channel layers 120b that overlaps the channel support 122 is also omitted in FIG. 1F to help illustrate example embodiments of the present disclosure.

Referring to FIGS. 1E and 1F, the channel support 122 may extend lengthwise (i.e., longitudinally) in the first direction X and may be between an adjacent pair of lower channel layers 120b in the third direction Z. The channel support 122 may also be between the pair of lower source/drain regions 140 in the first direction X.

In some embodiments, the channel support 122 may be spaced apart from the lower source/drain regions 140 (e.g., in the first direction X) by a pair of inner spacers 176, respectively, as shown in FIGS. 1E-F. For example, the inner spacers 176 may be on opposite sides of the channel support 122, respectively, in the first direction X. In some embodiments, the inner spacers 176 may be between the channel support 122 and the lower source/drain regions 140, respectively, in the first direction X. More particularly, the inner spacers 176 may be between end portions 122-E of the channel support 122 and the lower source/drain regions 140, respectively, in the first direction X. In some embodiments, each inner spacer 176 may be in contact with (e.g., may be directly on) a side surface of the channel support 122 and a side surface of a respective one of the lower source/drain regions 140. For example, end portions 122-E in the first direction X of the channel support 122 may be in contact with (e.g., may be directly on) side surfaces of the inner spacers 176, respectively. The inner spacers 176 and the channel support 122 may be between the lower channel layers 120b in the third direction Z, as shown in FIG. 1E. In some other embodiments, different from that shown, the inner spacers 176 may be omitted and the channel support 122 (e.g., the end portions 122-E of the channel support 122) may be in contact with (e.g., may be directly on) side surfaces of the lower source/drain regions 140.

In some embodiments, the lower channel layers 120b may protrude beyond the channel support 122 in the first direction X and the second direction Y. For example, the lower gate structure 170b (e.g., the lower conductive gate 174b) may be on opposing side surfaces of the channel support 122 in the second direction Y (see FIG. 1D), the inner spacers 176 may respectively be on opposing side surfaces of the channel support 122 in the first direction X, and the lower channel layers 120b may protrude beyond the opposing side surfaces of the channel support 122 in the first direction X and the second direction Y.

In some embodiments, a width of the channel support 122 in the second direction Y may increase toward the lower source/drain regions 140, as shown in FIG. 1F. That is, the width of the channel support 122 in the second direction Y may increase when moving toward the lower source/drain regions 140 in the first direction X. For example, the channel support 122 may have a middle portion 122-M and end portions 122-E in the first direction X. The end portions 122-E may oppose each other (i.e., may be opposite to each other) in the first direction X. In some embodiments, the end portions 122-E of the channel support 122 may be wider in the second direction Y than the middle portion 122-M of the channel support 122, as shown in FIG. 1F. In other words, the channel support 122 may be wider at the end portions 122-E and narrower at the middle portion 122-M. For example, the channel support 122 may have a bowtie or hourglass shape in a top view, although embodiments of the present disclosure are not limited thereto. As another example, the end portions 122-E of the channel support 122 may have a trapezoidal shape in a top view, although embodiments of the present disclosure are not limited thereto.

As described above with reference to FIGS. 1A-F, the lower transistor Tb of the integrated circuit device 100 includes channel supports 122 between adjacent ones of the lower channel layers 120b. The channel supports 122 may provide mechanical stability and structural support for the lower channel layers 120b to mitigate or avoid physical deformation thereto such as bending of the lower channel layers 120b during fabrication and/or operation of the integrated circuit device 100. Accordingly, the performance and reliability of the integrated circuit device 100 may be improved. Further, the channel supports 122 may allow for the length of the lower channel layers 120b to be extended without risking deformation thereto, which may offer performance advantages and increased design flexibility for the integrated circuit device 100.

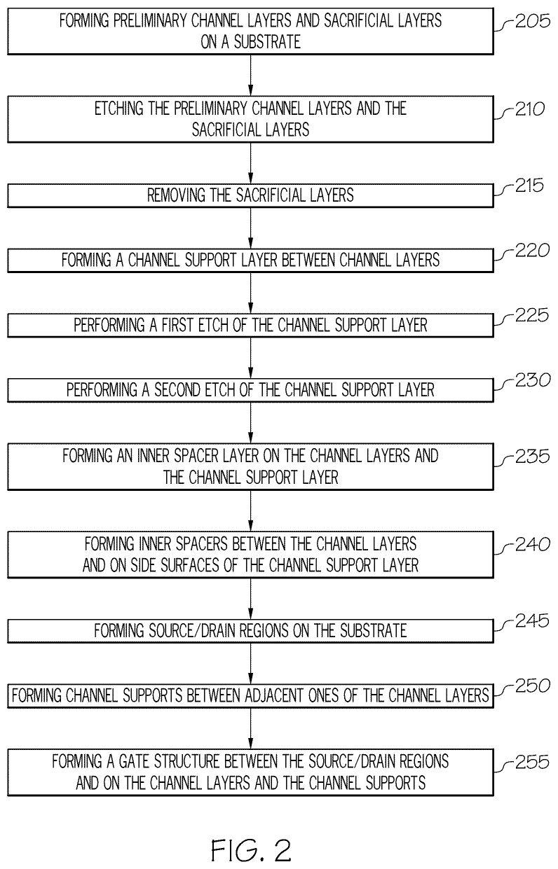

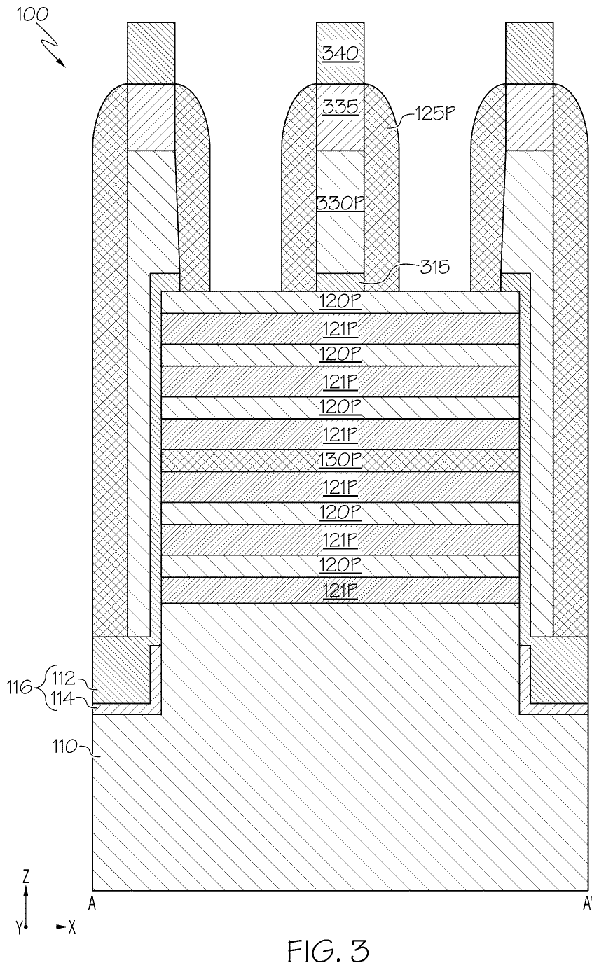

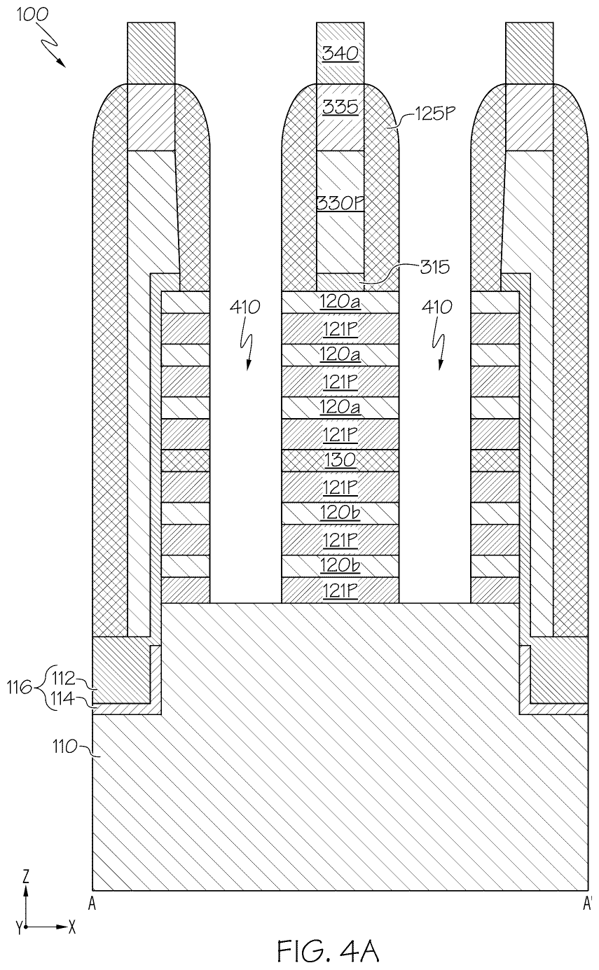

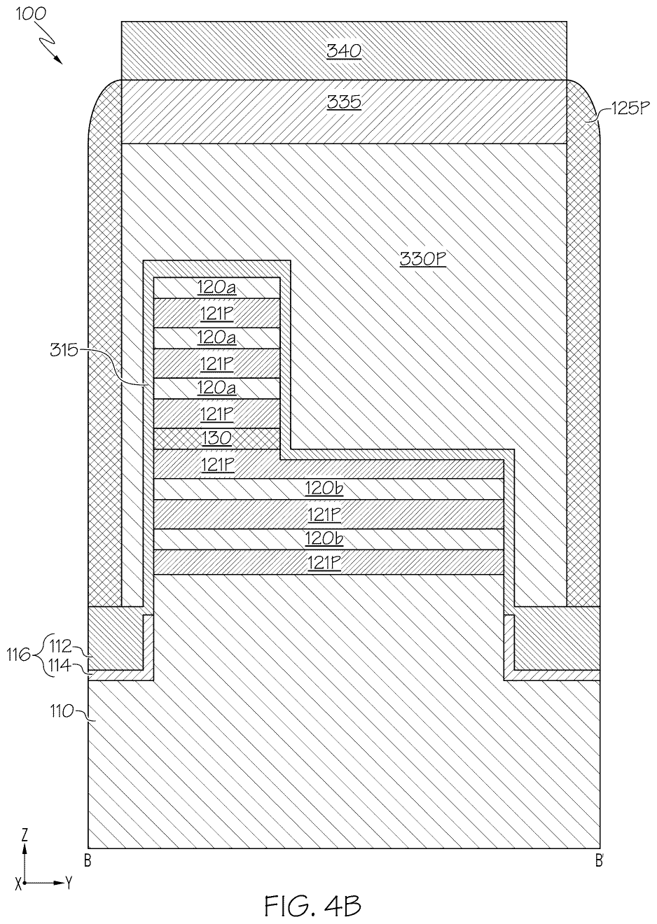

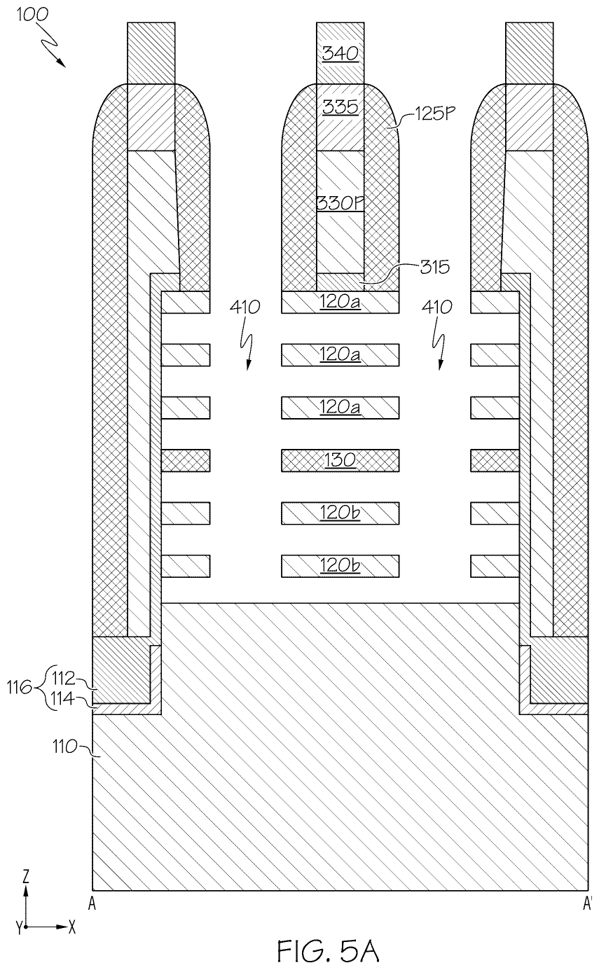

FIG. 2 is a flowchart illustrating a method of forming an integrated circuit device according to some embodiments. FIGS. 3, 4A, 4B, 5A, 5B, 6A, 6B, 7, 8, 9, 10, 11A, 11B, 12A, and 12B are schematic cross-sectional views illustrating a method of forming an integrated circuit device according to some embodiments. In particular, FIGS. 3, 4A, 5A, 6A, 7, 8, 9, 10, 11A, and 12A are schematic cross-sectional views corresponding to the line A-A′ of FIG. 1B. FIGS. 4B, 5B, 6B, 11B, and 12B are schematic cross-sectional views corresponding to the line B-B′ of FIG. 1B.

Referring to FIGS. 2 and 3, preliminary channel layers 120P and sacrificial layers 121P may be formed on a substrate 110 (Block 205 in FIG. 2). The preliminary channel layers 120P may be alternately stacked with the sacrificial layers 121P on the substrate 110 in the third direction Z.

The preliminary channel layers 120P may be semiconductor layers. In some embodiments, the preliminary channel layers 120P may include, for example, silicon (e.g., may be silicon layers). The sacrificial layers 121P may have an etch selectivity (i.e., may exhibit etch selectivity) with respect to the preliminary channel layers 120P, allowing for the sacrificial layers 121P to be selectively removed in a subsequent operation. In some embodiments, the sacrificial layers 121P may include, for example, silicon germanium (e.g., may be silicon germanium layers).

A layer 330P that is on top of the sacrificial layers 121P may also be a sacrificial layer and may be replaced with metal in a subsequent operation. The layer 330P may be on top of the stack preliminary channel layers 120P and sacrificial layers 121P and, in some embodiments, may extend on sidewalls of the stack of preliminary channel layers 120P and sacrificial layers 121P. In some embodiments, the layer 330P may include, for example, silicon. A layer 315 that is under the layer 330P may also be a sacrificial layer and may be replaced with metal in a subsequent operation. The layer 315 may be on top of the stack of preliminary channel layers 120P and sacrificial layers 121P and, in some embodiments, may extend on sidewalls of the stack of preliminary channel layers 120P and sacrificial layers 121P. In some embodiments, the layer 315 may include, for example, insulating material(s) (e.g., silicon oxide). In some other embodiments, the layers 315 and 330P may be a single layer (e.g., may include the same material) rather than two different layers.

A preliminary isolation region 130P may be between upper ones of the sacrificial layers 121P and lower ones of the sacrificial layers 121P. Shallow trench isolation (STI) regions 116 may be formed in the substrate 110 and may be on opposite sides (e.g., in the first direction X) of the stack of preliminary channel layers 120P and sacrificial layers 121P. The STI regions 116 may include a second insulating layer 112 and a second insulating liner 114. The second insulating liner 114 may extend adjacent the second insulating layer 112 and may be between the second insulating layer 112 and the substrate 110. The second insulating layer 112 and the second insulating liner 114 may include, for example, insulating material(s) (e.g., silicon oxide, silicon oxynitride, silicon nitride, silicon carbonitride, silicon boron carbonitride, and/or a low-k material).

Capping layers 335, 340 may be on the stack of preliminary channel layers 120P and sacrificial layers 121P. For example, the capping layers 335, 340 may be on top of the layer 330P. The capping layers 335, 340 may include, for example, insulating material(s) (e.g., silicon oxide, silicon oxynitride, silicon nitride, silicon carbonitride, silicon boron carbonitride, and/or a low-k material). In some embodiments, the capping layer 335 includes, for example, silicon nitride, and the capping layer 340 includes, for example, silicon oxide. Preliminary spacers 125P may be on the stack of preliminary channel layers 120P and sacrificial layers 121P. The preliminary spacers 125P may include, for example, insulating material(s) (e.g., silicon oxide, silicon oxynitride, silicon nitride, silicon carbonitride, silicon boron carbonitride, and/or a low-k material). The layers 315, 330P and the capping layers 335, 340 may be between the preliminary spacers 125P (e.g., in the first direction X).

Referring to FIGS. 2, 4A, and 4B, the preliminary channel layers 120P and the sacrificial layers 121P may be etched (Block 210 in FIG. 2). As a result, openings 410 may be formed in the preliminary channel layers 120P and the sacrificial layers 121P. The etching of the preliminary channel layers 120P may convert the preliminary channel layers 120P into upper channel layers 120a and lower channel layers 120b. For example, the lower channel layers 120b may be formed on the substrate 110 and may be spaced apart from each other in the third direction Z. The upper channel layers 120a may be formed on the lower channel layers 120b and may be spaced apart from each other in the third direction Z. The sacrificial layers 121P may be formed to be alternately stacked with the lower channel layers 120b and the upper channel layers 120a on the substrate 110 in the third direction Z.

In some embodiments, the capping layers 335, 340 and the preliminary spacers 125P may be used as an etch mask when etching the preliminary channel layers 120P and the sacrificial layers 121P. In some embodiments, the preliminary isolation region 130P may also be etched. The etching of the preliminary isolation region 130P may convert the preliminary isolation region 130P into an isolation region 130.

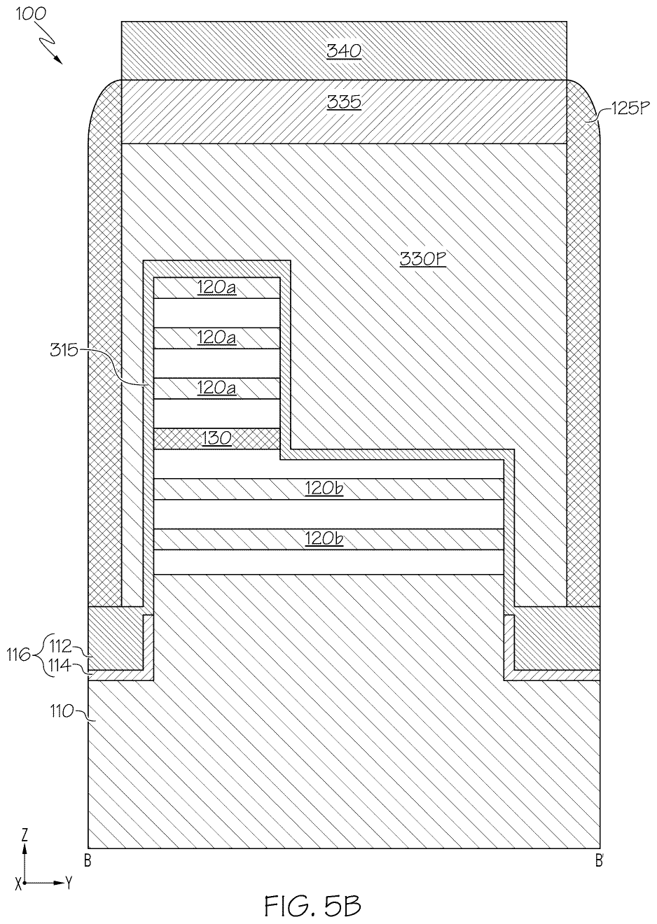

Referring to FIGS. 2, 5A, and 5B, the sacrificial layers 121P may be removed (Block 215 in FIG. 2). For example, the sacrificial layers 121P between the upper and lower channel layers 120a, 120b may be selectively removed, without removing the upper and lower channel layers 120a, 120b. In some embodiments, a selective etching process (e.g., selective wet or dry etching) may performed in the openings 410 to remove the sacrificial layers 121P. Spaces may be formed between adjacent ones of the upper channel layers 120a and between adjacent ones of the lower channel layers 120b by removing the sacrificial layers 121P. As used herein, the spaces may refer to openings or gaps that are formed between adjacent ones of the upper channel layers 120a and between adjacent ones of the lower channel layers 120b.

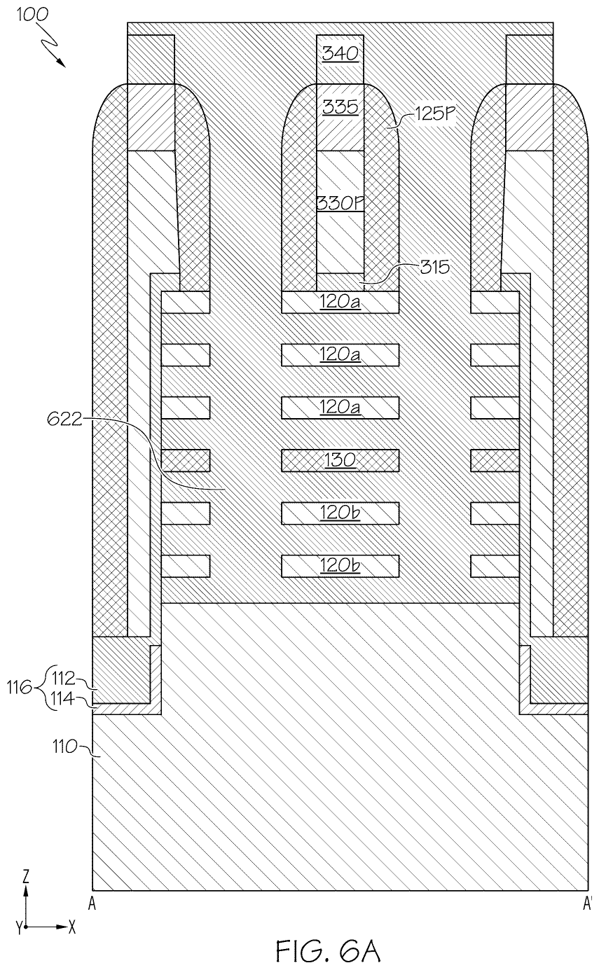

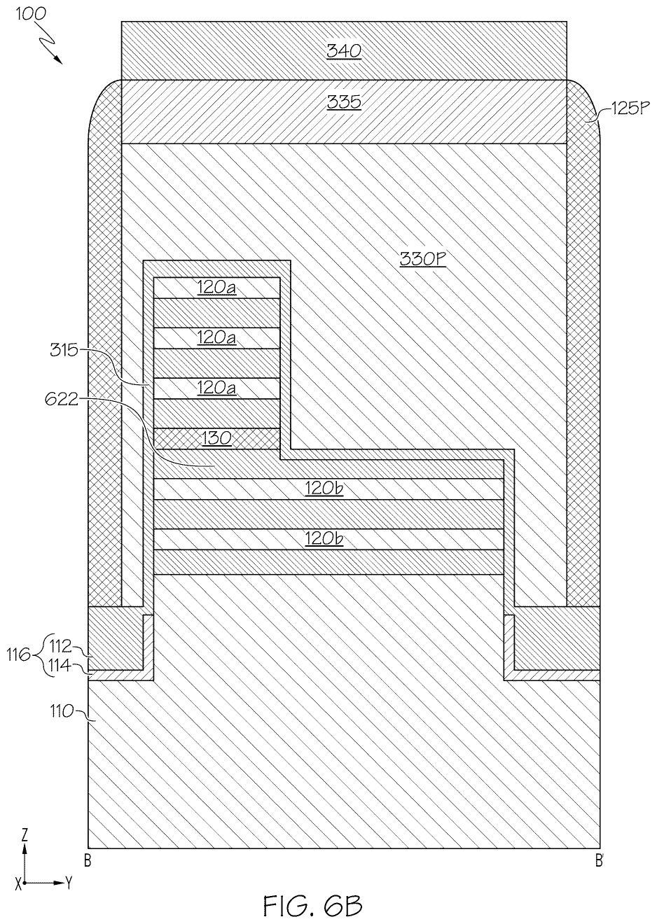

Referring to FIGS. 2, 6A, and 6B, a channel support layer 622 may be formed between the upper and lower channel layers 120a, 120b (Block 220 in FIG. 2). For example, the channel support layer 622 may be formed in the spaces left after removing the sacrificial layers 121P. That is, the channel support layer 622 may be formed between adjacent ones of the upper channel layers 120a and between adjacent ones of the lower channel layers 120b (e.g., in the third direction Z). The channel support layer 622 may also be formed between a lowermost one of the upper channel layers 120a and the isolation region 130, between an uppermost one of the lower channel layers 120b and the isolation region 130, and between a lowermost one of the lower channel layers 120b and the substrate 110. In some embodiments, the channel support layer 622 may be formed by depositing insulating material(s) into the openings 410 (see FIG. 5A). For example, a deposition process (e.g., a chemical vapor deposition (CVD) process and/or an atomic layer deposition (ALD) process) may be used to form (i.e., deposit) the channel support layer 622.

In some embodiments, the channel support layer 622 may substantially fill the openings 410 and may substantially fill the spaces between adjacent ones of the upper channel layers 120a and the spaces between adjacent ones of the lower channel layers 120b. The channel support layer 622 may also be formed on the capping layers 335, 340 and the preliminary spacers 125P.

The channel support layer 622 may include insulating material(s) (e.g., silicon oxide, silicon oxynitride, silicon nitride, silicon carbonitride, silicon boron carbonitride, and/or a low-k material). In some embodiments, the channel support layer 622 may include an oxide material such as silicon oxide. In some embodiments, the channel support layer 622, the second insulating layer 112, the layer 315, and the capping layer 340 may include a same material (e.g., silicon oxide), although the present disclosure is not limited thereto.

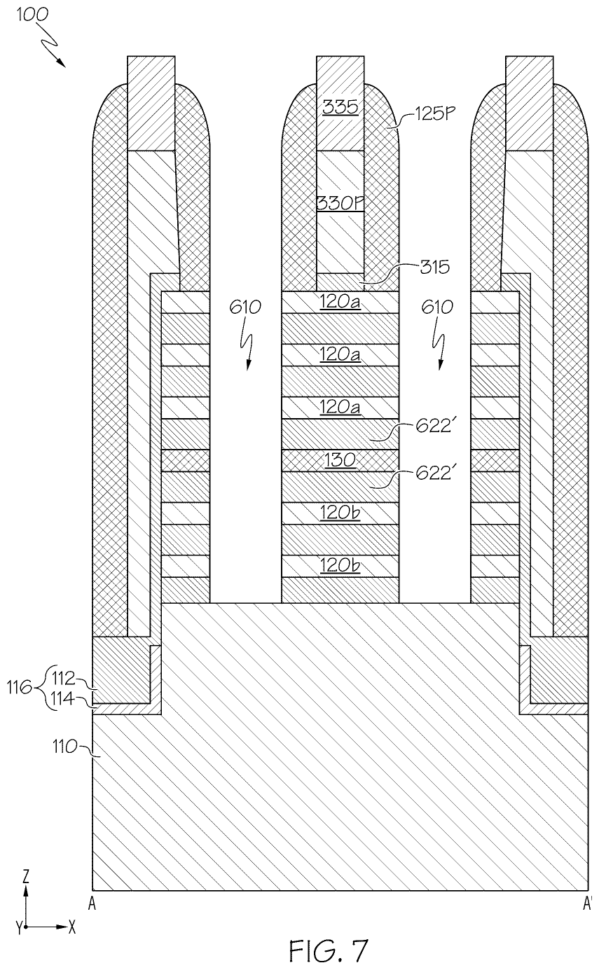

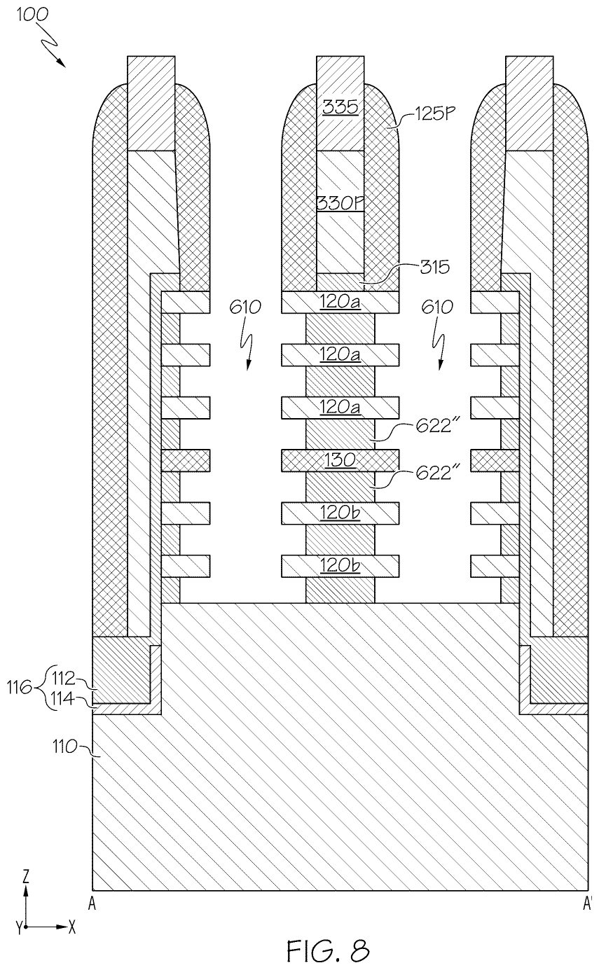

Referring to FIGS. 2 and 7, a first etch of the channel support layer 622 may be performed (Block 225 in FIG. 2). In other words, a first etching process may be performed on the channel support layer 622. For example, portions of the channel support layer 622 on opposite sides (e.g., in the first direction X) of the upper and lower channel layers 120a, 120b may be removed. As a result, openings 610 may be formed in the channel support layer 622. The etching of the channel support layer 622 may convert it into a channel support layer 622′. In some embodiments, side surfaces of the channel support layer 622′ may be substantially coplanar with (or collinear with) side surfaces of the upper and lower channel layers 120a, 120b.

In some embodiments, the capping layer 335 and the preliminary spacers 125P may be used as an etch mask when etching the channel support layer 622. The capping layer 340 may be removed in some embodiments when etching the channel support layer 622.

Referring to FIGS. 2 and 8, a second etch of the channel support layer 622′ may be performed (Block 230 in FIG. 2). In other words, a second etching process may be performed on the channel support layer 622′. For example, portions of the channel support layer 622′ between adjacent ones of the upper channel layers 120a (e.g., in the third direction Z) and between adjacent ones of the lower channel layers 120b (e.g., in the third direction Z) may be removed. That is, end portions of the channel support layer 622′ (e.g., in the first direction X) that are between the upper and lower channel layers 120a, 120b may be removed. The etching of the channel support layer 622′ may convert it into a channel support layer 622″. Side surfaces of the channel support layer 622″ may be non-coplanar with (or non-collinear with) side surfaces of the upper and lower channel layers 120a, 120b. For example, the side surfaces of the upper and lower channel layers 120a, 120b may protrude beyond the side surfaces of the channel support layer 622″ in the first direction X.

In some embodiments, a selective etching process (e.g., selective wet or dry etching) may performed in the openings 610 to remove portions of the channel support layer 622′ between the upper and lower channel layers 120a, 120b. For example, the channel support layer 622′ may have an etch selectivity (i.e., may exhibit etch selectivity) with respect to the upper and lower channel layers 120a, 120b, allowing for portions of the channel support layer 622′ to be removed without removing the channel layers 120a, 120b. Opposing side surfaces (i.e., opposing sidewalls) of the channel support layer 622′ (e.g., in the first direction X) may be etched to remove end portions thereof. Spaces may be formed between adjacent ones of the upper channel layers 120a and between adjacent ones of the lower channel layers 120b by removing the end portions of the channel support layer 622′. In some embodiments, inner spacers 176 may be formed in the spaces and on the channel support layer 622″, as will be described in greater detail below.

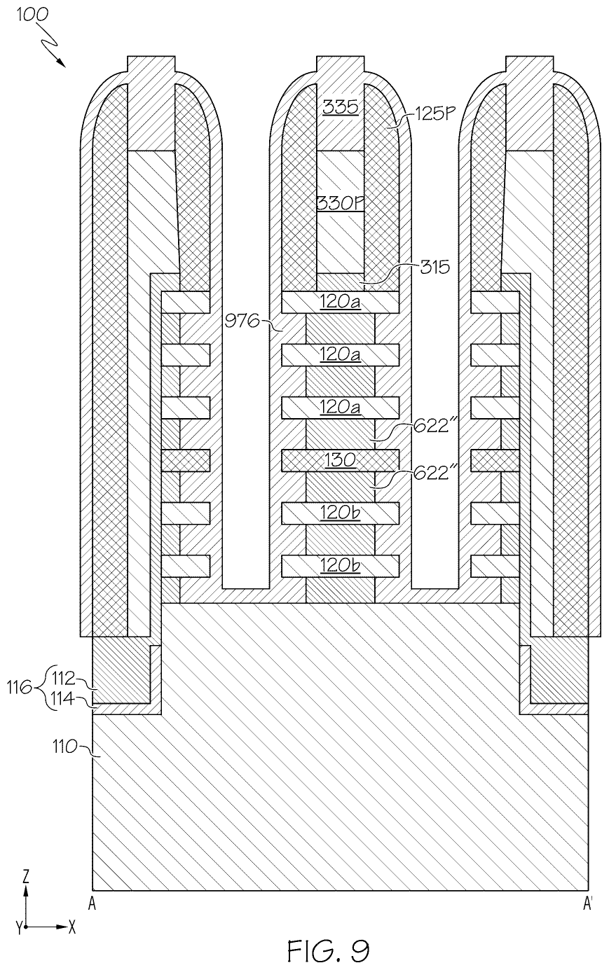

Referring to FIGS. 2 and 9, an inner spacer layer 976 may be formed on the upper and lower channel layers 120a, 120b and on the channel support layer 622″ (Block 235 in FIG. 2). For example, the inner spacer layer 976 may be formed on opposing side surfaces of the upper and lower channel layers 120a, 120b (e.g., in the first direction X) and on opposing side surfaces of the channel support layer 622″ (e.g., in the first direction X). The inner spacer layer 976 may extend between adjacent ones of the upper channel layers 120a and between adjacent ones of the lower channel layers 120b (e.g., in the third direction Z). More particularly, the inner spacer layer 976 may be formed in the spaces between adjacent ones of the upper channel layers 120a and between adjacent ones of the lower channel layers 120b that were left after removing the end portions of the channel support layer 622′. The inner spacer layer 976 may also be formed between a lowermost one of the upper channel layers 120a and the isolation region 130, between an uppermost one of the lower channel layers 120b and the isolation region 130, and between a lowermost one of the lower channel layers 120b and the substrate 110. The inner spacer layer 976 may also be formed on the capping layer 335 and the preliminary spacers 125P.

In some embodiments, the inner spacer layer 976 may be formed by depositing insulating material(s) into the openings 610 (see FIG. 8) on lower surfaces and sidewalls thereof. For example, a deposition process (e.g., a CVD process and/or an ALD process) may be used to form (i.e., deposit) the inner spacer layer 976. The inner spacer layer 976 may include insulating material(s) (e.g., silicon oxide, silicon oxynitride, silicon nitride, silicon carbonitride, silicon boron carbonitride, and/or a low-k material). In some embodiments, the inner spacer layer 976 may include a nitride material such as silicon nitride. In some embodiments, the inner spacer layer 976, the second insulating liner 114, and the capping layer 335 may include a same material (e.g., silicon nitride), although the present disclosure is not limited thereto.

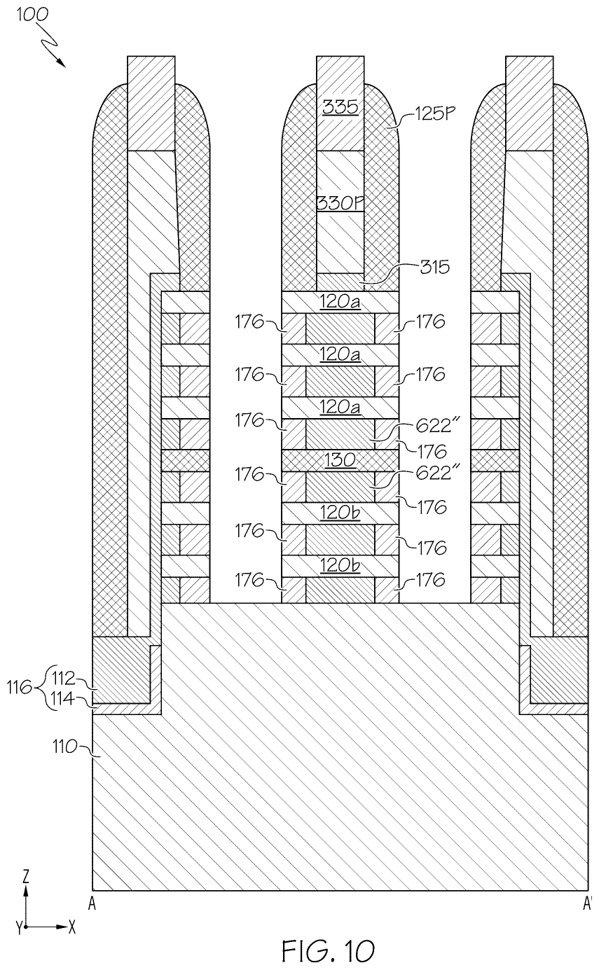

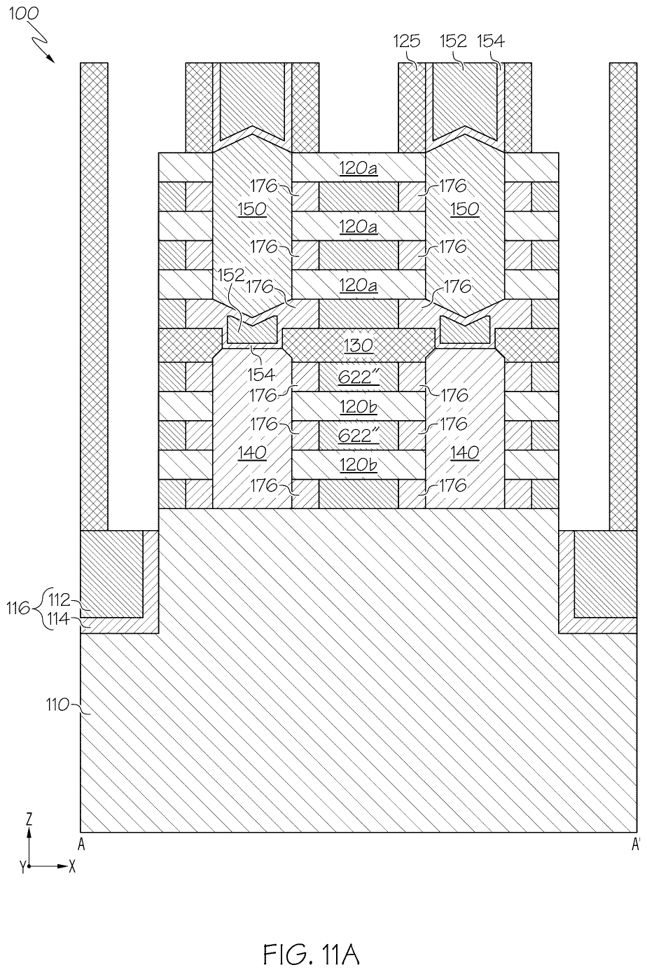

Referring to FIGS. 2 and 10, inner spacers 176 may be formed between the upper and lower channel layers 120a, 120b and on side surfaces (e.g., opposing side surfaces) of the channel support layer 622″ (Block 240 in FIG. 2). For example, the inner spacers 176 may be formed between adjacent ones of the upper channel layers 120a (e.g., in the third direction Z) and between adjacent ones of the lower channel layers 120b (e.g., in the third direction Z). The inner spacers 176 may also be formed between a lowermost one of the upper channel layers 120a and the isolation region 130, between an uppermost one of the lower channel layers 120b and the isolation region 130, and between a lowermost one of the lower channel layers 120b and the substrate 110. The inner spacer layer 976 (see FIG. 9) may be etched to form the inner spacers 176. For example, portions of the inner spacer layer 976 on side surfaces of the upper and lower channel layers 120a, 120b, on side surfaces of the isolation region 130, and on side surfaces of the preliminary spacers 125P may be selectively removed by an etching process. A portion of the inner spacer layer 976 on the substrate 110 that is free of overlap with the upper and lower channel layers 120a, 120b may also be selectively removed by the etching process. In some embodiments, the etching process may be a selective etching process (e.g., selective wet or dry etching) to remove portions of the inner spacer layer 976, without removing the upper and lower channel layers 120a, 120b. The etching of the inner spacer layer 976 may convert the inner spacer layer 976 into the inner spacers 176.

In some embodiments, a pair of inner spacers 176 may be between each adjacent pair of upper channel layers 120a and between each adjacent pair of lower channel layers 120b. For example, each pair of inner spacers 176 may be spaced apart (or separated) from each other by the channel support layer 622″ (e.g., in the first direction X) and may respectively be on opposing side surfaces of the channel support layer 622″. In some embodiments, a side surface of each inner spacer 176 may be substantially coplanar with (or collinear with) a side surface of a channel layer 120a, 120b thereon.

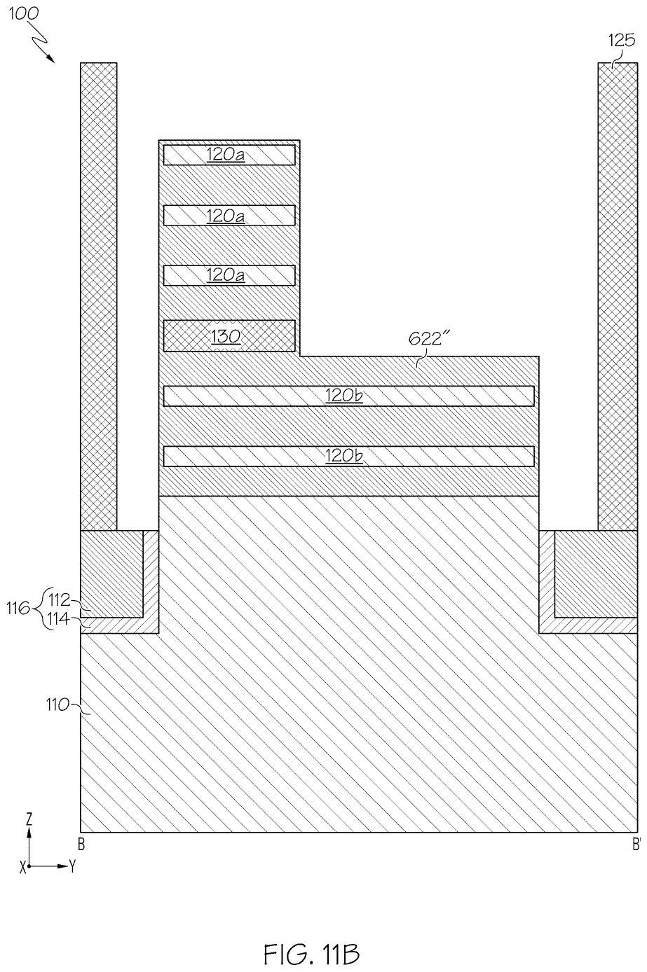

Referring to FIGS. 2, 11A, and 11B, lower and upper source/drain regions 140, 150 may be formed on the substrate 110. (Block 245 in FIG. 2). For example, a pair of lower source/drain regions 140 may be formed on opposing side surfaces (i.e., opposite sides) of the lower channel layers 120b (e.g., in the first direction X), respectively. A pair of upper source/drain regions 150 may be formed on opposing side surfaces (i.e., opposite sides) of the upper channel layers 120a (e.g., in the first direction X), respectively. For example, the lower and upper source/drain regions 140, 150 may be formed adjacent to the channel support layer 622″ (e.g., in the first direction X), with the inner spacers 176 therebetween.

In some embodiments, the lower and upper source/drain regions 140, 150 may be epitaxially grown. For example, the upper source/drain regions 150 may be formed by performing an epitaxial growth process using the upper channel layers 120a as a seed layer, and the upper source/drain regions 150 may be epitaxially grown from opposing side surfaces of the upper channel layers 120a (e.g., in the first direction X). As another example, the lower source/drain regions 140 may be formed by performing an epitaxial growth process using the lower channel layers 120b and/or the substrate 110 as a seed layer, and the lower source/drain regions 140 may be epitaxially grown from opposing side surfaces of the lower channel layers 120b (e.g., in the first direction X) and/or an upper surface of the substrate 110. The lower source/drain regions 140 and the upper source/drain regions 150 may each include a semiconductor layer (e.g., a silicon (Si) layer, a silicon carbide (SiC) layer, and/or a silicon germanium (SiGe) layer) and may additionally include dopants in the semiconductor layer. The inner spacers 176 may be between the source/drain regions 140, 150 and the channel support layer 622″ (e.g., in the first direction X).

As shown in FIGS. 11A and 11B, the layers 315 and 330P and the capping layer 335 of FIG. 10 may be removed. The preliminary spacers 125P may be converted into upper spacers 125 by the removal of the layer 315, the layer 330P, and/or the capping layer 335. A first insulating layer 152 and a first insulating liner 154 may be formed on an upper surface of each of the upper source/drain regions 150 and between, in the third direction Z, the lower and upper source/drain regions 140, 150.

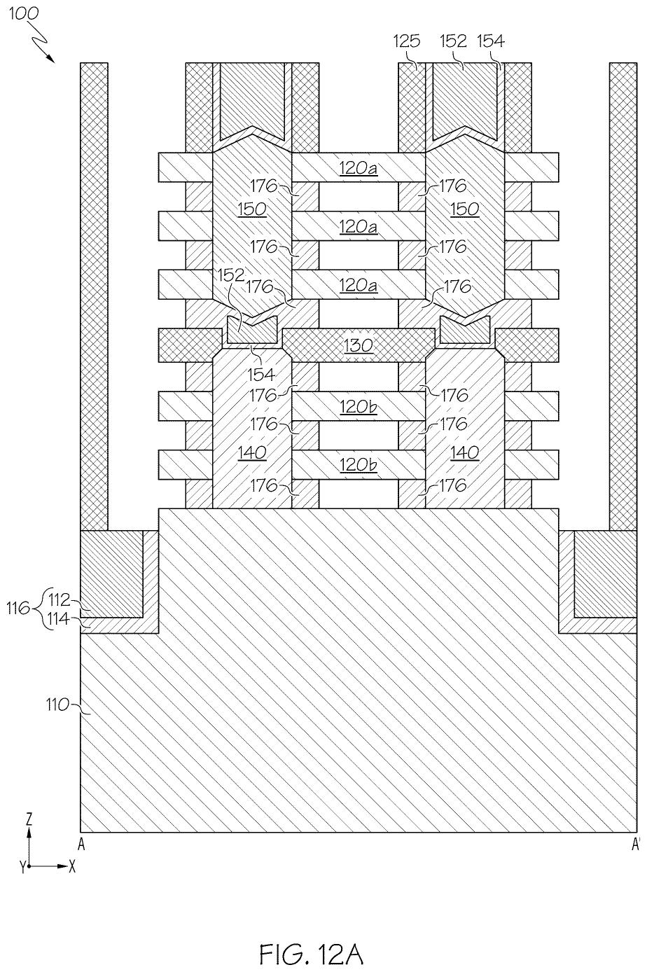

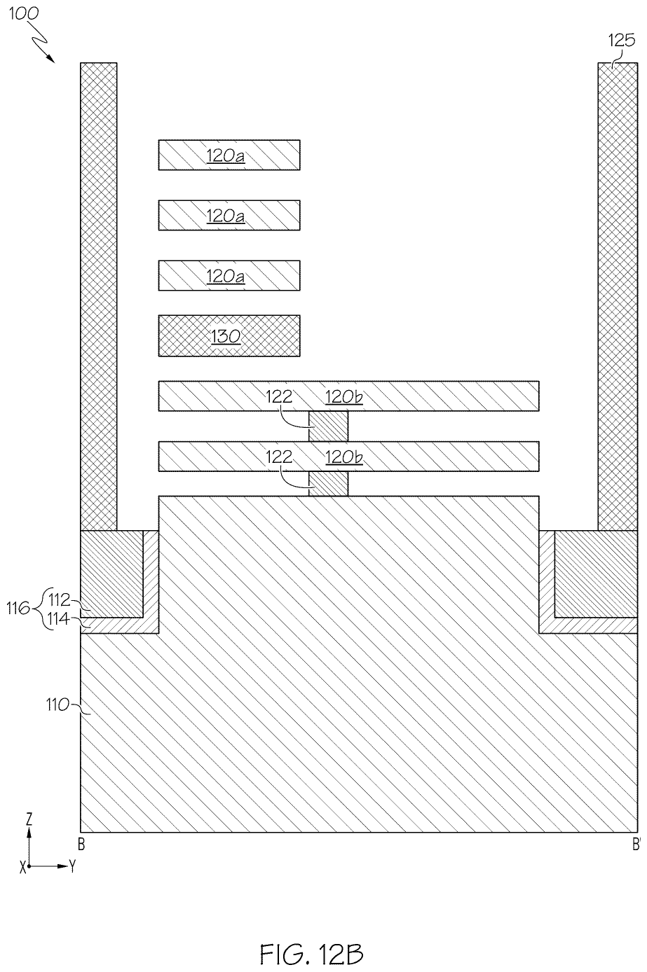

Referring to FIGS. 2, 12A, and 12B, channel supports 122 may be formed between adjacent ones of the lower channel layers 120b (Block 250 in FIG. 2). In some embodiments, a third etch of the channel support layer 622″ (see FIGS. 11A-B) may be performed to form the channel supports 122. In other words, a third etching process may be performed on the channel support layer 622″ to form the channel supports 122. For example, portions of the channel support layer 622″ may be selectively removed without removing all of the channel support layer 622″ to form the channel supports 122. In other words, the etching of the channel support layer 622″ may convert the channel support layer 622″ into the channel supports 122.

In some embodiments, the channel support layer 622″ may be partially removed between the lower channel layers 120b and between a lowermost one of the lower channel layers 120b and the substrate 110 to form the channel supports 122. The lower channel layers 120b may be spaced apart from each other in the third direction Z, with the channel support 122 therebetween. The channel supports 122 may be stacked and spaced apart from each other in the third direction Z, and may overlap the lower channel layers 120b and the substrate 110 in the third direction Z.

In some embodiments, portions of the channel support layer 622″ that are between the upper channel layers 120a may be removed (i.e., may be entirely removed). For example, an upper portion of the channel support layer 622″ that is between the upper source/drain regions 150 (e.g., in the first direction X) may be entirely removed by the etching process. As a result, the channel supports 122 may not be formed between adjacent ones of the upper channel layers 120a, although embodiments of the present disclosure are not limited thereto.

In some embodiments, a selective etching process (e.g., selective wet or dry etching) may performed to remove portions of the channel support layer 622″. For example, the channel support layer 622″ may have an etch selectivity (i.e., may exhibit etch selectivity) with respect to the upper and lower channel layers 120a, 120b, the upper and lower source/drain regions 150, 140, and the inner spacers 176, allowing for portions of the channel support layer 622″ to be removed without removing the channel layers 120a, 120b, the source/drain regions 150, 140, and the inner spacers 176. In some embodiments, the selective etching process may cause a width of the channel support 122 in the second direction Y to increase toward the lower source/drain regions 140 (see FIG. 1F). For example, the etching process may be isotropic (i.e., may be an isotropic etching process), which may form a bowtie or hourglass shape for the channel supports 122 in a top view, although embodiments are not limited thereto. The isotropic etching process, for example, may allow for more uniform removal of portions of the channel support layer 622″ between the lower channel layers 120b to form the channel supports 122, which may improve the mechanical stability provided by the channel supports 122.

Referring to FIG. 2 and back to FIGS. 1B-D, a gate structure 170 may be formed between the upper and lower source/drain regions 150, 140 and on the upper and lower channel layers 120a, 120b and on the channel supports 122 (Block 255 in FIG. 2). For example, the gate insulator 172 may be formed on the upper and lower channel layers 120a, 120b, on the channel supports 122, and on the inner spacers 176. The upper conductive gate 174a may be formed on the gate insulator 172 between the upper source/drain regions 150, and the lower conductive gate 174b may be formed on the gate insulator 172 between the lower source/drain regions 140. As shown in FIG. 1D, the upper conductive gate 174a may extend on an upper surface, a lower surface, and opposing side surfaces of each upper channel layer 120a. The lower conductive gate 174b may extend on an upper surface, a lower surface, and opposing side surfaces of each lower channel layer 120b. The lower conductive gate 174b may also extend on opposing side surfaces of each channel support 122. In some embodiments, the upper and lower conductive gates 174a, 174b may be formed by depositing one or more conductive layers (e.g., a metal layer and/or work function layer(s)), with an upper portion thereof forming the upper conductive gate 174a and a lower portion thereof forming the lower conductive gate 174b. The dummy gate structures 171 may also be formed on the STI regions 116 and on opposite sides (e.g., in the first direction X), respectively, of the gate structure 170. Accordingly, the integrated circuit device 100 shown in FIGS. 1B-D may be formed.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein.

By way of example, embodiments of the present disclosure are described and illustrated herein with reference to integrated circuit devices including stacked transistors. It will be understood, however, that the integrated circuit devices of the present disclosure are not limited thereto and may include any type of transistor (or semiconductor device), including, but not limited to, transistors having a gate-all-around (GAA) structure and/or vertically stacked channels.

In the description above, example embodiments may be described with reference to regions of particular conductivity types. It will be appreciated that opposite conductivity type devices may be formed by simply reversing the conductivity of the n-type and p-type layers in each of the above embodiments. Thus, it will be appreciated that the present disclosure covers both n-channel and p-channel devices for each different device structure.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of the stated features, steps, operations, elements, components and/or groups, but do not preclude the presence or addition of one or more other features, steps, operations, elements, components and/or groups thereof.

It will be understood that, although the terms “first,” “second,”, “third,” etc. may be used throughout this specification to describe various elements, these elements should not be limited by these terms. Rather, these terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terms “surround” or “cover” or “fill” as used herein may not require completely surrounding or covering or filling the described elements or layers, but may, for example, refer to partially surrounding or covering or filling the described elements or layers. Components or layers described with reference to “overlap” in a particular direction may be at least partially obstructed by one another when viewed along a line extending in the particular direction or in a plane perpendicular to the particular direction.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The term “connected” may include physical and/or electrical connections.

Spatially relative terms such as “below” or “above” or “upper” or “lower” or “top” or “bottom” or “side” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

Example embodiments are described herein with reference to the accompanying drawings, which may include cross-section illustrations that are schematic illustrations of idealized embodiments (and intermediate structures). Many different forms and embodiments are possible without deviating from the teachings of this disclosure. Accordingly, the present disclosure should not be construed as limited to the example embodiments set forth herein. As such, it will be understood by those of ordinary skill in the art that various changes in form and details may be made therein without departing from the scope as defined herein. In the drawings, the sizes and relative sizes of layers and regions may be exaggerated for clarity. Additionally, variations from the shapes of the illustrations as a result, for example, of manufacturing techniques and/or tolerances, are to be expected.

Embodiments of the present disclosure are also described with reference to fabrication operations and flowchart diagrams. It will be appreciated that the steps shown in the fabrication operations and flowchart diagrams need not be performed in the order shown.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope is to be determined by the broadest permissible interpretation of the following claims and their equivalents, and shall not be restricted or limited by the foregoing detailed description.

1. An integrated circuit device, comprising:
a substrate;
a source/drain region on the substrate;
a plurality of channel layers spaced apart in a first direction perpendicular to an upper surface of the substrate and electrically connected to the source/drain region;
a gate structure extending in a second direction parallel to the upper surface of the substrate and at least partially surrounding the channel layers; and
a channel support between adjacent ones of the channel layers in the first direction,
wherein the gate structure extends on opposing side surfaces of the channel support in the second direction.

2. The integrated circuit device of claim 1, wherein the channel support comprises an insulating material.

3. The integrated circuit device of claim 1, wherein a width of the channel support in the second direction is less than a width of at least one of the channel layers in the second direction.

4. The integrated circuit device of claim 1, wherein the gate structure extends on an upper surface, a lower surface, and opposing side surfaces of at least one of the channel layers.

5. The integrated circuit device of claim 1, further comprising an inner spacer between the channel support and the source/drain region in a third direction parallel to the upper surface of the substrate and intersecting the second direction.

6. The integrated circuit device of claim 5, wherein the channel support comprises a first insulating material, and the inner spacer comprises a second insulating material different from the first insulating material.

7. The integrated circuit device of claim 5, wherein the inner spacer is between the gate structure and the source/drain region in the third direction, and
wherein the inner spacer is between the adjacent ones of the channel layers in the first direction.

8. The integrated circuit device of claim 1, wherein a width of the channel support in the second direction increases toward the source/drain region.

9. The integrated circuit device of claim 1, wherein the gate structure comprises a conductive gate and a gate insulator between the conductive gate and the channel layers, and
wherein the conductive gate extends on the opposing side surfaces of the channel support.

10. The integrated circuit device of claim 9, wherein the channel support comprises a first insulating material, and the gate insulator comprises a second insulating material different from the first insulating material.

11. The integrated circuit device of claim 1, wherein the channel support is a first channel support, and
wherein the integrated circuit device further comprises a second channel support between a lowermost one of the channel layers and the substrate in the first direction.

12. The integrated circuit device of claim 1, wherein the source/drain region is a lower source/drain region, the channel layers are lower channel layers, and the gate structure is a lower gate structure,
wherein the lower source/drain region, the lower channel layers, and the lower gate structure are included in a lower transistor,
wherein the integrated circuit device further comprises an upper transistor on the lower transistor, the upper transistor comprising:
an upper source/drain region on the lower source/drain region;
a plurality of upper channel layers spaced apart in the first direction and electrically connected to the upper source/drain region; and
an upper gate structure at least partially surrounding the upper channel layers, and
wherein at least one of the upper channel layers is free of overlap with the channel support in the first direction.

13. An integrated circuit device, comprising:
a substrate;
a pair of source/drain regions on the substrate;
a plurality of channel layers spaced apart in a first direction perpendicular to an upper surface of the substrate and between the pair of source/drain regions in a second direction parallel to the upper surface of the substrate;
a gate structure extending in a third direction parallel to the upper surface of the substrate and intersecting the second direction, the gate structure at least partially surrounding the channel layers; and
a channel support between adjacent ones of the channel layers in the first direction,
wherein at least one of the channel layers protrudes beyond opposing side surfaces of the channel support in the third direction.

14. The integrated circuit device of claim 13, wherein the channel support is a first channel support,
wherein the integrated circuit device further comprises a second channel support between a lowermost one of the channel layers and the substrate in the first direction, and
wherein the first channel support is spaced apart from the second channel support and overlaps the second channel support in the first direction.

15. The integrated circuit device of claim 13, further comprising a pair of inner spacers on opposite sides of the channel support, respectively, in the second direction,
wherein the pair of inner spacers are between the channel support and the pair of source/drain regions, respectively.

16. The integrated circuit device of claim 13, wherein a middle portion in the third direction of the at least one of the channel layers overlaps the channel support in the first direction.

17. A method of forming an integrated circuit device, the method comprising:
forming a plurality of channel layers on a substrate, the channel layers spaced apart in a first direction perpendicular to an upper surface of the substrate;
forming a channel support layer between the channel layers, the channel support layer comprising an insulating material;
selectively removing portions of the channel support layer without removing all of the channel support layer to form at least one channel support between adjacent ones of the channel layers in the first direction; and
forming a gate structure on the channel layers and on the at least one channel support, the gate structure at least partially surrounding the channel layers and extending on opposing side surfaces of the at least one channel support in a second direction intersecting the first direction.

18. The method of claim 17, further comprising:
forming a plurality of sacrificial layers alternately stacked with the channel layers in the first direction; and
removing the sacrificial layers to form spaces between the channel layers,
wherein forming the channel support layer between the channel layers comprises forming the channel support layer in the spaces between the channel layers.

19. The method of claim 17, further comprising forming a source/drain region on a side surface of at least one of the channel layers and adjacent to the channel support layer,
wherein the portions of the channel support layer are selectively removed without removing the source/drain region.

20. The method of claim 17, further comprising forming at least one inner spacer on a side surface of the channel support layer and between the adjacent ones of the channel layers,
wherein the insulating material included in the channel support layer is a first insulating material, and the inner spacer comprises a second insulating material different from the first insulating material.
